(19) United States
(12) Patent Application Publication
(10) Pub. No.: US 2013/0110464 A1
(43) Pub. Date: May 2, 2013

(54) MOUNTING APPARATUS, COMPONENT DEPLETION DETERMINATION METHOD, AND PROGRAM

(71) Applicant: Sony Corporation, Tokyo (JP)

(72) Inventor: Keisuke Ishida, Ibaraki (JP)

(73) Assignee: Sony Corporation, Tokyo (JP)

(21) Appl. No.: 13/661,854

(22) Filed: Oct. 26, 2012

(30) Foreign Application Priority Data
Nov. 2, 2011 (JP) 2011-241144

(51) Int. Cl. H05K 13/04; G06F 15/00

(52) U.S. Cl. 702/183; 29/714

(57) ABSTRACT

A mounting apparatus includes a supply unit, a holding unit, first and second sensors, and a controller. The supply unit is configured to supply an electronic component. The holding unit is configured to hold the electronic component supplied from the supply unit and mount the electronic component on a substrate. The first and second sensors are configured to detect a component depletion of the electronic component supplied from the supply unit. The controller performs a first component depletion determination process in which whether the component depletion of the electronic component is caused is determined on the basis of an output from the first sensor, and when it is determined that the component depletion is caused in the first component depletion determination process, perform a second component depletion determination process in which whether the component depletion is caused is determined on the basis of an output from the second sensor.

### BACKGROUND

The present disclosure relates to a technique of a mounting apparatus that mounts electronic components on a substrate, and the like.

From the past, there has been widely known a mounting apparatus that mounts electronic components such as a resistor and a capacitor on a mounting substrate.

In such a mounting apparatus, first, the electronic component supplied from a supply unit is sucked by a sucking nozzle. Then, the sucking nozzle that sucks the electronic component is moved on a mounting substrate, and the sucking nozzle is lowered, thereby mounting the electronic component onto the mounting substrate.

The supply unit is formed by arranging a plurality of tape feeders, for example. When the tape feeders run out of the electronic components, an operator is notified of a component depletion. In this case, the operator carries out a task for changing the tape feeders that run out of the electronic components for new tape feeders, for example.

Examples of a method of determining a component depletion include a method of managing a remaining count of the electronic components for each tape feeder and determining that the components are depleted when the remaining count becomes zero and a method of determining that the components are depleted when non-sucking errors of the electronic components successively occur in the sucking nozzle (see, for example, Japanese Patent Application Laid-open No. 2001-267800 (paragraph 0020)).

### SUMMARY

In the method of determining that the components are depleted by managing the remaining count, it may be impossible to exactly manage the remaining count in the tape feeders in many cases, for example, in the case where an in-use tape feeder (tape feeder having some electronic components used) is used. Therefore, it is difficult to accurately determine that the components are depleted by this method.

In the same way, it may also be impossible to accurately determine that the components are depleted in the case where the component depletion is determined according to the non-sucking error by the sucking nozzle. For example, in the case where a nozzle failure such as a nozzle clogging or an operation failure of the tape feeder occurs, the non-sucking errors by the sucking nozzle successively occur.

In such a case, although the electronic components remain in the tape feeders actually, the mounting apparatus erroneously recognizes that the components are depleted, and an operator is notified of the component depletion. In this case, there is a problem in that the electronic components remain in the tape feeder actually, but the operator changes the tape feeder for new one, for example.

In view of the above-mentioned circumstances, it is desirable to provide a technique capable of accurately determining a component depletion in a supply unit.

According to an embodiment of the present disclosure, there is provided a mounting apparatus including a supply unit, a holding unit, a first sensor and a second sensor, and a control unit.

The supply unit is configured to supply an electronic component.

The holding unit is configured to hold the electronic component supplied from the supply unit and mount the electronic component on a substrate.

The first sensor and a second sensor are configured to detect a component depletion of the electronic component supplied from the supply unit.

The controller is configured to perform a first component depletion determination process in which whether the component depletion of the electronic component is caused is determined on the basis of an output from the first sensor, and when it is determined that the component depletion is caused in the first component depletion determination process, perform a second component depletion determination process in which whether the component depletion is caused is determined on the basis of an output from the second sensor.

In the mounting apparatus, at least two component depletion determination processes are carried out. Therefore, it is possible to correctly determine the component depletion of the electronic component supplied from the supply unit. Thus, it is possible to overcome a problem of exchanging a tape feeder with new one even though the electronic component remains in the tape feeder in actuality, for example.

In the mounting apparatus, the second sensor may be an image sensor configured to take an image of the supply unit.

In this case, the controller may determine, in the second component depletion determination process, whether the component depletion is caused on the basis of image information of the supply unit, which is an output from the image sensor.

In the mounting apparatus, the second component depletion determination process, which is the second time of the component depletion determination process, is performed on the basis of the image information of the supply unit. In this case, typically, in the case where the electronic component exists in the image of the supply unit, it is determined that the component depletion is not generated, and in the case where the electronic component does not exist in the image of the supply unit, it is determined that the component depletion is generated. In this way, the component depletion determination process is carried out on the basis of the image of the supply unit in the second component depletion determination process, so it is possible to determine the component depletion of the electronic component more accurately.

In the mounting apparatus, the first sensor may be a holding detection sensor configured to detect whether the electronic component is held by the holding unit.

The controller may determine, in the first component depletion determination process, whether the electronic components are not held by the holding unit successively on the basis of an output from the holding detection sensor, and when the electronic components are not held successively, determines that the component depletion is caused.

The mounting apparatus may further include a notification unit configured to notify an operator of an abnormality in the mounting apparatus.

When it is determined that the component depletion is caused in the first component depletion determination process, and it is determined that the component depletion is not caused in the second component depletion determination process, the controller may determine that the abnormality is generated in the mounting apparatus and notify the abnormality by the notification unit.

In the mounting apparatus, in the case where it is determined that the abnormality is generated in the mounting apparatus, the abnormality in the mounting apparatus is notified. The abnormality in the mounting apparatus is notified from the mounting apparatus, so the operator can recognize not the component depletion of the electronic component but the abnormality in the mounting apparatus.

The mounting apparatus may further include an abnormality detection sensor configured to identify a cause of the abnormality in the mounting apparatus.

The controller may identify the cause of the abnormality in the mounting apparatus on the basis of an output from the abnormality detection sensor and notify the cause of the abnormality in the mounting apparatus by the notification unit.

As a result, the operator can know the cause of the abnormality in the mounting apparatus easily.

The mounting apparatus may further include a repair unit configured to repair the abnormality in the mounting apparatus.

When it is determined that the component depletion is caused in the first component depletion determination process, and it is determined that the component depletion is not caused in the second component depletion determination process, the controller may determine that the abnormality is generated in the mounting apparatus and repair the abnormality by the repair unit.

In the mounting apparatus, the abnormality in the mounting apparatus is automatically repaired by the repair unit.

In the case where the mounting apparatus further includes an abnormality detection sensor configured to identify a cause of the abnormality in the mounting apparatus, the controller may identify the cause of the abnormality in the mounting apparatus on the basis of an output from the abnormality detection sensor and repair the abnormality identified in the mounting apparatus by the repair unit.

In the mounting apparatus, the cause of the abnormality in the mounting apparatus is automatically identified, and the abnormality in the mounting apparatus is automatically repaired.

In the case where the mounting apparatus further includes an abnormality detection sensor configured to identify a cause of an abnormality in the mounting apparatus, when it is determined that the component depletion is caused in the first component depletion determination process, and it is determined that the component depletion is not caused in the second component depletion determination process, the controller may determine that the abnormality is generated in the mounting apparatus and identify the cause of the abnormality in the mounting apparatus on the basis of an output from the abnormality detection sensor.

In the mounting apparatus, the cause of the abnormality in the mounting apparatus is automatically identified.

In the case where the mounting apparatus further includes the notification unit and the repair unit, the controller may determine whether the cause of the abnormality identified on the basis of the output from the abnormality detection sensor is capable of being repaired by the repair unit, repair the abnormality in the mounting apparatus by the repair unit, when the abnormality is capable of being repaired, and notify the cause of the abnormality by the notification unit, when the abnormality is not capable of being repaired.

According to another embodiment of the present disclosure, there is provided a component depletion determination method including performing a first component depletion determination process in which whether a component depletion of an electronic component is caused is determined on the basis of an output from a first sensor that detects the component depletion of the electronic component supplied from a supply unit that supplies the electronic component to a holding unit that holds the electronic component and mounts the electronic component on a substrate.

When it is determined that the component depletion is caused in the first component depletion determination process, a second component depletion determination process is performed in which whether the component depletion is caused is determined on the basis of an output from a second sensor that detects the component depletion of the electronic component.

According to another embodiment of the present disclosure, there is provided a program causing a mounting apparatus to execute a step of performing a first component depletion determination process in which whether a component depletion of an electronic component is caused is determined on the basis of an output from a first sensor that detects the component depletion of the electronic component supplied from a supply unit that supplies the electronic component to a holding unit that holds the electronic component and mounts the electronic component on a substrate.

A step of performing, when it is determined that the component depletion is caused in the first component depletion determination process, a second component depletion determination process in which whether the component depletion is caused is determined on the basis of an output from a second sensor that detects the component depletion of the electronic component is executed.

As described above, according to the embodiments of the present disclosure, it is possible to provide the technique capable of accurately determining the component depletion in the supply unit.

These and other objects, features and advantages of the present disclosure will become more apparent in light of the following detailed description of best mode embodiments thereof, as illustrated in the accompanying drawings.

### BRIEF DESCRIPTION OF DRAWINGS

FIG. 1 is a front view showing a mounting apparatus according to an embodiment of the present disclosure;

FIG. 2 is a plan view of the mounting apparatus;

FIG. 3 is an enlarged view showing a mounting head of the mounting apparatus;

FIG. 4 is a block diagram showing the structure of the mounting apparatus; and

FIG. 5 is a flowchart showing an operation at a time when a non-sucking error of an electronic component by a sucking nozzle occurs.

### DETAILED DESCRIPTION OF EMBODIMENTS

Hereinafter, embodiments of the present disclosure will be described with reference to the drawings.

### First Embodiment

(Structure of Mounting Apparatus 100 and structures of Respective Units)

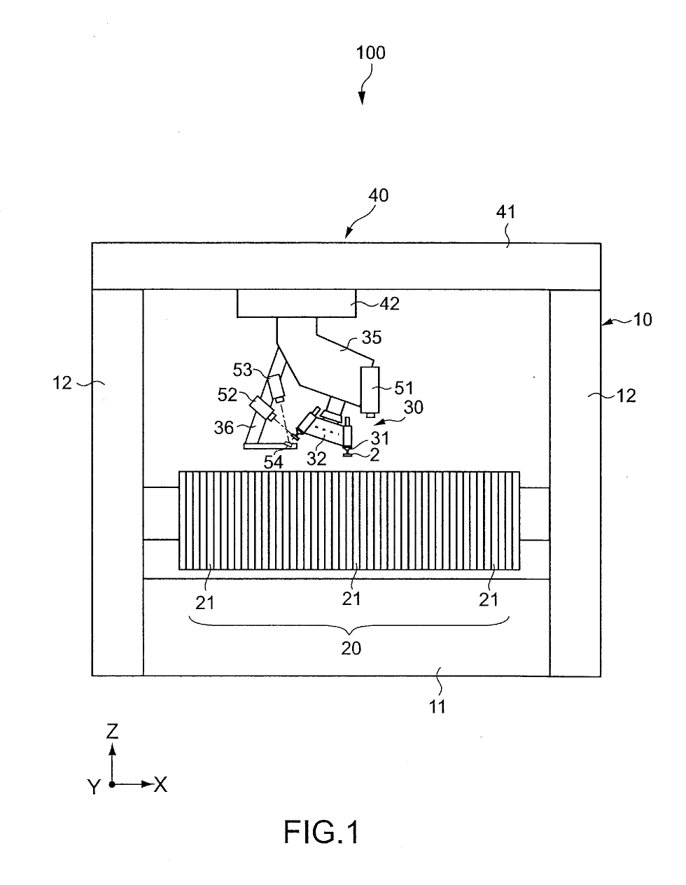

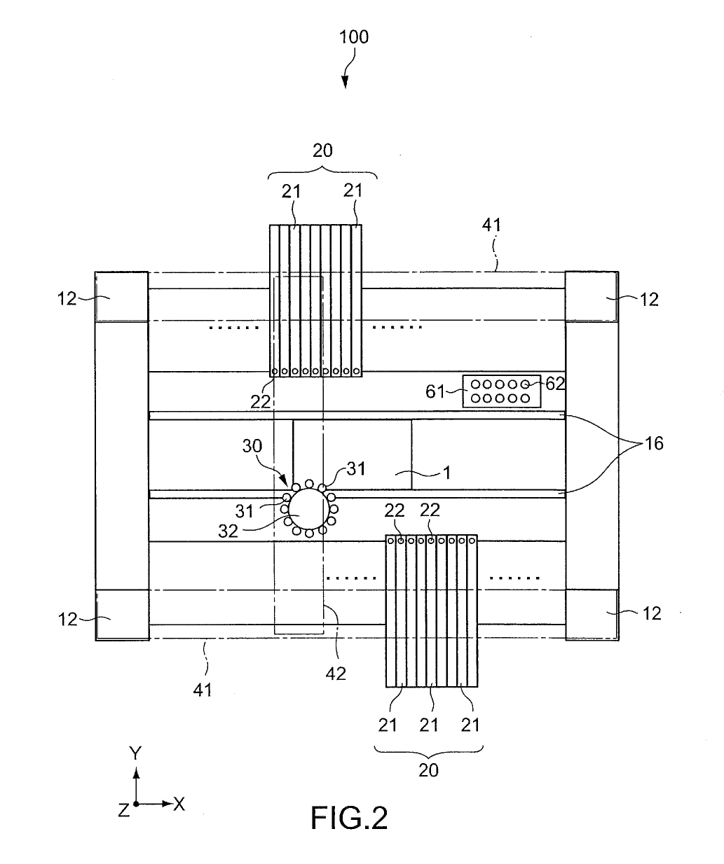

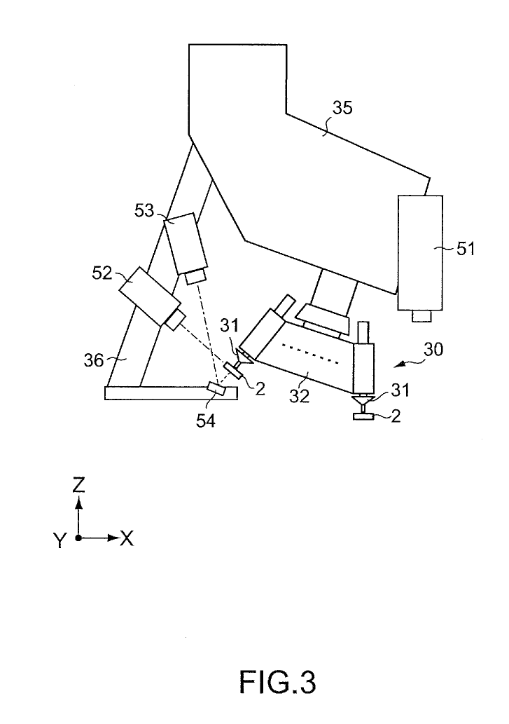

FIG. 1 is a front view showing a mounting apparatus 100 according to an embodiment of the present disclosure. FIG. 2 is a plan view of the mounting apparatus 100 shown in FIG. 1. FIG. 3 is an enlarged view showing a mounting head 30 of the mounting apparatus 100.

As shown in those figures, the mounting apparatus 100 includes a frame 10, a conveyor 16 that conveys a substrate 1, and supply units 20 that are provided on both sides of the conveyor 16 and supply an electronic component 2. The mounting apparatus 100 also includes the mounting head 30 including sucking nozzles 31 that each suck the electronic component 2 supplied from the supply units 20 and mount the electronic component 2 on the substrate 1 and a head drive mechanism 40 that drives the mounting head 30.

Further, the mounting apparatus 100 is provided with a first image pickup unit 51 that takes an image of an alignment mark provided on the substrate 1 from above and takes an image of the supply units 20 from above. The mounting apparatus 100 is provided with a second image pickup unit 52 that takes an image of the sucking nozzle 31 from a side thereof with the sucking nozzle 31 holding the electronic component 2 and a third image pickup unit 53 that takes an image of the sucking nozzle 31 from below through a mirror 54 with the sucking nozzle 31 holding the electronic component 2. In addition, the mounting apparatus 100 is provided with a nozzle changer 61 for changing the sucking nozzle 31, which is disposed between the supply unit 20 and the conveyor 16.

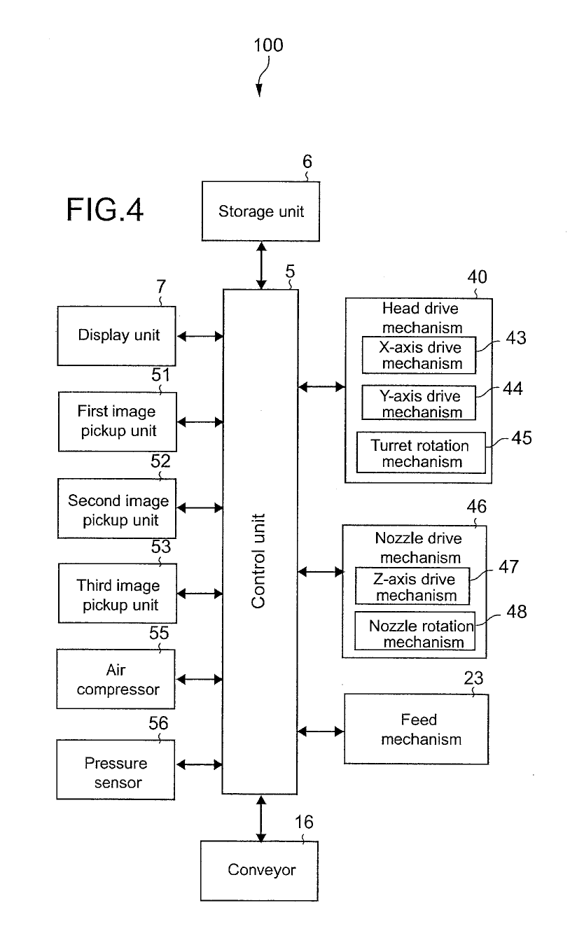

FIG. 4 is a block diagram showing the structure of the mounting apparatus 100.

As shown in FIG. 4, the mounting apparatus 100 includes a controller 5, a storage unit 6, a display unit 7, an air compressor 55, a pressure sensor 56, a nozzle drive mechanism 46, and the like in addition to the conveyor 16, the head drive mechanism 40, the first image pickup unit 51, the second image pickup unit 52, the third image pickup unit 53, and the like.

In descriptions below, the structure of the mounting apparatus 100 will be described in detail while mainly referring to FIGS. 1 to 3 and referring to FIG. 4 as appropriate.

The conveyor 16 is extended along an X-axis direction and conveys the substrate 1 handed over from another apparatus provided on an upstream side of the mounting apparatus 100 to a predetermined position. Further, after the electronic component 2 is mounted on the substrate 1, the conveyor 16 conveys the substrate 1 and hands the substrate 1 over to another apparatus provided on a downstream side.

The supply unit 20 is constituted of a plurality of tape feeders 21 arranged along the X-axis direction. The tape feeders 21 each include a reel around which a carrier tape that accommodates the electronic components 2 therein is wound and a feed mechanism 23 (see, FIG. 4) that feeds the carrier tape in step feed. Inside the carrier tape, the electronic components 2 such as a resistor, a capacitor, and a coil are accommodated for each type. A supply window 22 is formed on an upper surface at an end portion of each of the tape feeders 21, and the electronic components 2 are supplied via the supply window 22.

The frame 10 includes a base 11 provided at a bottom portion thereof and a plurality of support columns 12 fixed to the base 11.

The head drive mechanism 40 includes two X beams 41 provided across upper portions of the plurality of support columns 12 in the X-axis direction and a Y beam 42 extended between the two X beams 41 in a Y-axis direction. It should be noted that in FIG. 2, the X beam 41 on the front side and the Y beam 42 are illustrated with dashed-dotted lines to help understanding of the figure.

The Y beam 42 is attached to lower sides of the two X beams 41 so that the Y beam 42 is movable with respect to the X beams 41 in the X-axis direction. The X beams 41 have an X-axis drive mechanism 43 (see FIG. 4) for moving the Y beam 42 in the X-axis direction inside, and by driving the X-axis drive mechanism 43, the Y beam 42 is moved in the X-axis direction below the X beams 41.

Below the Y beam 42, a carriage 35 is attached which holds the mounting head 30. The carriage 35 is attached so as to be movable with respect to the Y beam 42 in the Y-axis direction. The Y beam 42 has a Y-axis drive mechanism 44 (see FIG. 4) for moving the carriage 35 in the Y-axis direction inside, and by driving the Y-axis drive mechanism 44, the carriage 35 is moved in the Y-axis direction below the Y beam 42.

By driving the X-axis drive mechanism 43 and the Y-axis drive mechanism 44, the mounting head 30 (sucking nozzles 31) provided below the carriage 35 is moved in the X- and Y-axis directions. Examples of the X-axis drive mechanism 43 and the Y-axis drive mechanism 44 include a ball screw drive mechanism, a belt drive mechanism, and a linear motor drive mechanism.

The mounting head 30 includes a turret 32 rotatably attached to the carriage 35 and the plurality of sucking nozzles 31 attached to the turret 32 at regular intervals in a circumferential direction of the turret 32.

The turret 32 is rotatable about an oblique axis as a center axis. By driving a turret rotation mechanism 45 (see FIG. 4) of the head drive mechanism 40, the turret 32 rotates about the axis as the center axis.

The sucking nozzles 31 are attached to the turret 32 so that axis lines of the sucking nozzles 31 tilt with respect to the rotation axis of the turret 32.

The sucking nozzles 31 are each movably supported by the turret 32 along the axis-line direction. The sucking nozzles 31 are also rotatably supported by the turret 32. By driving a Z-axis drive mechanism 47 (see FIG. 4) of the nozzle drive mechanism 46, the sucking nozzles 31 move in the axis-line direction (vertical direction) at a predetermined timing. Also by driving a nozzle rotation mechanism 48 (see FIG. 4), the sucking nozzles 31 rotate about the axis lines at a predetermined timing.

Out of the plurality of sucking nozzles 31, the sucking nozzle 31 disposed on a lowermost position (sucking nozzle 31 disposed on a right end position in FIGS. 1 to 3) has the axis line directed to a vertical line. In the following description, the position of the sucking nozzle 31 which has the axis line directed to the vertical line is referred to as an operation position. The sucking nozzle 31 disposed at the operation position is sequentially switched by the rotation of the turret 32.

The sucking nozzles 31 are connected to the air compressor 55 (see FIG. 4). The sucking nozzles 31 are capable of sucking and releasing the electronic components 2 in accordance with switching between negative and positive pressures of the air compressor 55.

In the air compressor 55 or an air flow path between the sucking nozzle 31 and the air compressor 55, the pressure sensor 56 (see FIG. 4) is provided. The pressure sensor 56 detects an air pressure (blow pressure) at the time when the sucking nozzle 31 is set to a positive pressure by the air compressor 55.

To the carriage 35, the first image pickup unit 51 is provided which takes an image of an alignment mark provided on the substrate 1 from above and takes an image of the supply units 20 from above. The first image pickup unit 51 has an image sensor (second sensor) such as a CCD (Charge Coupled Device) sensor and a CMOS (Complementary Metal Oxide Semiconductor) sensor.

The first image pickup unit 51 is moved integrally with the carriage 35 and the mounting head 30 when the carriage 35 and the mounting head 30 are moved along the X axis direction and Y axis direction. When the first image pickup unit 51 takes the image of the supply unit 20 from above, the first image pickup unit 51 is moved above the supply window of the supply unit 20 and takes an image of the position of the supply window from above.

On the basis of an image of the supply unit 20 taken by the first image pickup unit 51 (image sensor), the controller 5 determines whether the component depletion of the electronic component 2 actually occurs in the supply units 20 (second component depletion determination process). In this sense, the first image pickup unit 51 (image sensor) has the function as a sensor for detecting the component depletion of the electronic component 2.

To the carriage 35, a support unit 36 is attached which supports the second image pickup unit 52, the third image pickup unit 53, and the mirror 54. The second image pickup unit 52, the third image pickup unit 53, and the mirror 54 are moved integrally with the carriage 35 and the mounting head 30 when the carriage 35 and the mounting head 30 are moved along the X axis direction and the Y axis direction.

The second image pickup unit 52 is disposed at such a position that the second image pickup unit 52 is capable of taking an image of the sucking nozzle 31 at the highest position (in FIGS. 1 to 3, sucking nozzle 31 disposed at the left end side) out of the plurality of the sucking nozzles 31 from the side thereof. The third image pickup unit 53 is disposed at such a position that the image pickup unit 53 is capable of taking an image of the sucking nozzle 31 at the highest position out of the plurality of the sucking nozzles 31 from below through the mirror 54.

It should be noted that in the following description, out of the plurality of sucking nozzles 31, the sucking nozzle 31 disposed at such a position that an image thereof is taken by the second image pickup unit 52 and the third image pickup unit 53 is referred to as the sucking nozzle 31 disposed at an image pickup position.

The second image pickup unit 52 and the third image pickup unit 53 have an image sensor (first sensor) such as a CCD sensor and a CMOS sensor.

On the basis of the image of the sucking nozzle 31 taken from the side thereof by the second image pickup unit 52, the controller 5 can determine a bad sucking (so-called standing sucking) that a side surface of the electronic component 2 is sucked by the sucking nozzle 31. Further, on the basis of the image of the sucking nozzle 31 taken from below by the third image pickup unit 53, the controller 5 can determine a sucking position and the like of the electronic component 2 with respect to the sucking nozzle 31. On the basis of the sucking position of the electronic component 2 with respect to the sucking nozzle 31, the controller 5 corrects the position of the sucking nozzle 31 with respect to the substrate 1 when the electronic component 2 is mounted on the substrate 1.

In addition, on the basis of the image taken by at least one of the second image pickup unit 52 and the third image pickup unit 53, the controller 5 can determine whether the electronic component 2 is sucked by the sucking nozzle 31 or not. That is, on the basis of the image taken by at least one of the second image pickup unit 52 and the third image pickup unit 53, the controller 5 can determine a non-sucking error by the sucking nozzle 31.

In general, in the case where multiple non-sucking errors of the electronic components 2 supplied from the same tape feeder 21 occur in succession, the controller 5 determines that the tape feeder 21 runs out of the component (first component depletion determination process). In this sense, at least one of the second image pickup unit 52 and the third image pickup unit 53 has a function as a sensor for detecting the component depletion of the electronic component 2.

The nozzle changer 61 disposed between the supply unit 20 and the conveyor 16 has a plurality of nozzle holding holes 62 to and from which the sucking nozzles 31 are attachable and detachable. The nozzle changer 61 is used when the sucking nozzle 31 is changed in accordance with a change of a kind of the substrate 1 or when the sucking nozzle 31 is changed in response to a nozzle failure such as a chipping of a tip end of the sucking nozzle 31, for example.

The controller 5 is configured by a CPU (Central Processing Unit), for example. The controller 5 performs various calculations on the basis of various programs stored in the storage unit 6 and performs overall control of units of the mounting apparatus 100. The process by the controller 5 will be described later.

The storage unit 6 has a nonvolatile memory in which various programs necessary for the control by the controller 5 are stored and a volatile memory used as a work area of the controller 5. The various programs may be read by a portable recording medium such as an optical disk and a semiconductor memory.

The display unit 7 is configured by a liquid crystal display, an EL (Electro-Luminescence) display, or the like. The display unit 7 notifies an operator of an occurrence of an abnormality in the mounting apparatus 100 or notifies the operator of a cause of the abnormality on the basis of the control by the controller 5. The abnormality in the mounting apparatus 100 includes a nozzle failure such as a nozzle clogging, an operation failure of a movement of the sucking nozzle 31 in the vertical direction, an operation failure of the tape feeder 21, or a positional displacement of the tape feeder 21, for example.

(Explanation of Operation)

Next, an operation of the mounting apparatus 100 according to this embodiment will be described. First, a basic operation of the mounting apparatus 100 will be described.

First, the controller 5 conveys the substrate 1 by the conveyor 16 and positions the substrate 1 at a predetermined position. Next, the controller 5 drives the X-axis drive mechanism 43 and the Y-axis drive mechanism 44 to move the first image pickup unit 51 to the alignment mark on the substrate 1. Then, the controller 5 takes an image of the alignment mark provided on the substrate 1 by the first image pickup unit 51. A plurality of alignment marks are provided on the substrate 1, so the controller 5 moves the first image pickup unit 51 to each of the alignment marks so that the first image pickup unit 51 takes an image of each of the alignment marks. As a result, the controller 5 can recognize the position of the substrate 1.

Subsequently, the controller 5 drives the X-axis drive mechanism 43 and the Y-axis drive mechanism 44 to move the sucking nozzle 31 disposed at the operation position to the position of the supply window 22 of the tape feeder 21.

Then, the controller 5 drives the Z-axis drive mechanism 47 to lower the sucking nozzle 31 disposed at the operation position, and switches the sucking nozzle 31 to a negative pressure by the air compressor 55. As a result, the electronic component 2 is sucked by a tip end portion of the sucking nozzle 31. After the electronic component 2 is sucked by the sucking nozzle 31, the controller 5 lifts the sucking nozzle 31 with the Z-axis drive mechanism 47.

Next, the controller 5 drives the turret rotation mechanism 45 to rotate the turret 32 and switches the sucking nozzle 31 disposed at the operation position. Upon switching the sucking nozzle 31 disposed at the operation position, the controller 5 drives the Z-axis drive mechanism 47 to lower the sucking nozzle 31 so that the electronic component 2 is sucked by a tip end of the sucking nozzle 31. As described above, the electronic components 2 are sucked by the plurality of sucking nozzles 31.

The second image pickup unit 52 and the third image pickup unit 53 each take an image of the sucking nozzle 31 that holds the electronic component 2, which is moved to the image pickup position (left end position in FIGS. 1 to 3) by the rotation of the turret 32. The sucking nozzle 31 disposed at the image pickup position is switched sequentially by rotating the turret 32.

Upon obtaining the image of the sucking nozzle 31 from the side thereof from the second image pickup unit 52, on the basis of the image obtained, the controller 5 determines whether or not the side surface of the electronic component 2 is sucked by the sucking nozzle 31. That is, the controller 5 determines whether a standing sucking occurs or not. In the case where the standing sucking occurs, the electronic component 2 is discarded into a dust box (not shown).

Upon obtaining the image of the sucking nozzle 31 from below from the third image pickup unit 53, on the basis of the image obtained, the controller 5 determines a sucking position and the like of the electronic component 2 with respect to the sucking nozzle 31.

Further, on the basis of the image information obtained from at least one of the second image pickup unit 52 and the third image pickup unit 53, the controller 5 determines whether or not the electronic component 2 is sucked by the sucking nozzle 31. That is, the controller 5 determines whether a non-sucking error by the sucking nozzle 31 occurs or not. A process in the case where the non-sucking error occurs will be described later.

After the electronic components 2 are sucked by the sucking nozzles 31, the controller 5 drives the X-axis drive mechanism 43 and the Y-axis drive mechanism 44 to move the mounting head 30 (sucking nozzles 31) onto the substrate 1. Then, the controller 5 aligns the position of the sucking nozzle 31 at the operation position with the position of the substrate 1 on which the electronic component 2 is mounted. At the time of the alignment, on the basis of the sucking position of the electronic component 2 with respect to the sucking nozzle 31, the controller 5 corrects the position of the sucking nozzle 31.

When the position of the sucking nozzle 31 is aligned with the position of the substrate 1, the controller 5 moves the sucking nozzle 31 downward. Then, the controller 5 switches the sucking nozzle 31 from the negative pressure to the positive pressure by the air compressor 55. As a result, the electronic component 2 is detached from the sucking nozzle 31 and is mounted on the substrate 1.

Subsequently, the controller 5 rotates the turret 32 to switch the sucking nozzle 31 disposed at the operation position. Then, the controller 5 aligns the position of the sucking nozzle 31 newly disposed at the operation position with the position on the substrate 1. Then, the sucking nozzle 31 disposed at the operation position is moved downward, and the electronic component 2 sucked by the tip end of the sucking nozzle 31 is mounted on the substrate 1.

When all the electronic components 2 sucked by the sucking nozzles 31 are mounted on the mounting substrate 1, the mounting head 30 is moved again from the position above the mounting substrate 1 to the position above the supply unit 20. When the mounting of the electronic components 2 is terminated, the substrate 1 is discharged by the conveyor 16.

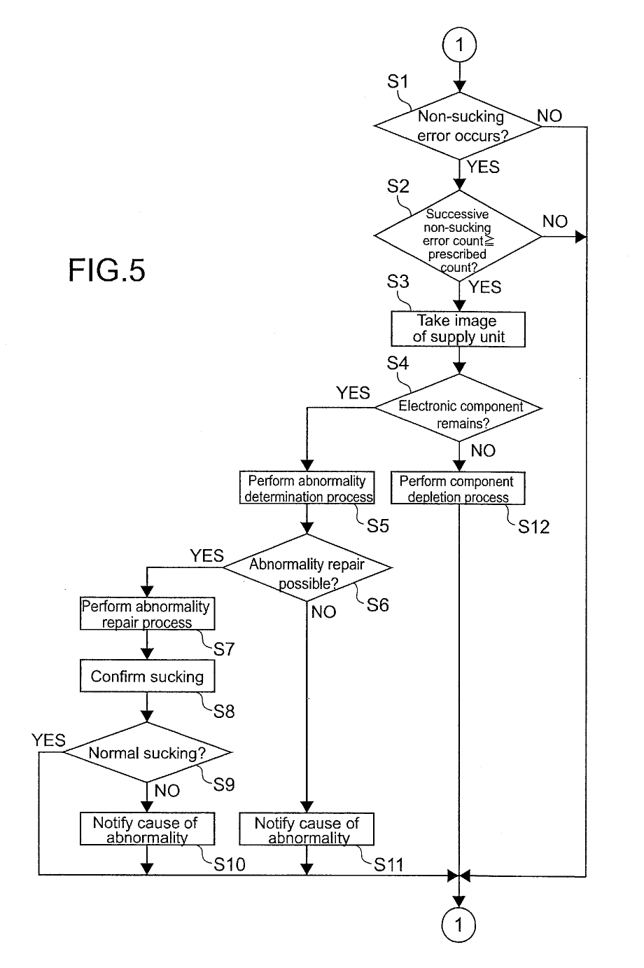

Then, a description will be given on an operation in the case where the non-sucking error of the electronic component 2 by the sucking nozzle 31 occurs. FIG. 5 is a flowchart showing the operation in the case where the non-sucking error of the electronic component 2 by the sucking nozzle 31 occurs.

First, on the basis of at least one of the images of the sucking nozzle 31 taken by the second image pickup unit 52 from the side thereof and the image of the sucking nozzle 31 taken by the third image pickup unit 53 from below, the controller 5 determines whether the non-sucking error by the sucking nozzle 31 occurs or not (Step 1). In the case where the electronic component 2 is sucked by the sucking nozzle 31 (NO in Step 1), the process returns to Step 1, and the controller 5 determines again whether the non-sucking error of the electronic component 2 by the sucking nozzle 31 occurs or not.

In the case where the non-sucking error of the electronic component 2 by the sucking nozzle 31 occurs (YES in Step 1), the controller 5 determines whether a successive non-sucking error count is equal to or more than a prescribed count or not (Step 2). The successive non-sucking error count is counted in the case where the non-sucking errors occur successively in the same tape feeder 21. In Steps 1 and 2, the controller 5 determines whether the non-sucking errors of the electronic components 2 by the sucking nozzles 31 occur successively in the same tape feeder 21, thereby determining whether or not the component depletion is generated in the tape feeder 21 (first component depletion determination process).

The prescribed count mentioned above is a count serving as a standard for the determination of the component depletion in the tape feeder 21. The prescribed count is set to, for example, four or five but is not limited to those. The prescribed count may be set for each of the electronic components 2 differently. For example, a larger prescribed count is set for the electronic component 2 which is more likely to cause the non-sucking error than the electronic component 2 which is less likely to cause the non-sucking error.

In the case where the successive non-sucking error count is less than the prescribed count (NO in Step 2), the process returns to Step 1, and the controller 5 determines again whether the non-sucking error occurs or not.

On the other hand, in the case where the successive non-sucking error count is equal to or more than the prescribed count (YES in Step 2), the controller 5 controls the X-axis drive mechanism 43 and the Y-axis drive mechanism 44 to move the first image pickup unit 51 to a position above the supply window of the tape feeder 21 in which the successive non-sucking error count exceeds the prescribed count. Then, the controller 5 causes the first image pickup unit 51 to take an image of an area including at least the supply window of the tape feeder 21 from above the tape feeder 21 (Step 3).

The first image pickup unit 51 may be configured so as to take not only the image of the area including the supply window but also an image of the electronic component 2 in the carrier tape which is to be fed next (or after next) by the feed mechanism 23. With this structure, the controller 5 is capable of more accurately determining whether or not the electronic component 2 remains in the tape feeder 21 in which the successive non-sucking error occurs.

Upon taking the image of the tape feeder 21 by the first image pickup unit 51, the controller 5 determines whether or not the electronic component 2 remains in the tape feeder 21 by image processing (Step 4). The controller 5 determines whether or not the electronic component 2 remains in the tape feeder 21, thereby determining whether the component depletion actually occurs or not (second component depletion determination process).

In this embodiment, the two component depletion determination processes are carried out as described above, so it is possible to determine the component depletion in the supply unit 20 accurately. As a result, it is possible to prevent the tape feeder 21 from being changed for new one although the electronic component 2 remains in the tape feeder 21 in actuality and prevent the operation of the mounting apparatus 100 from being stopped due to the component depletion.

Further, in this embodiment, the second component depletion determination process is carried out on the basis of the image of the supply unit 20 actually taken, with the result that the component depletion process is more accurately carried out.

In the case where the electronic component 2 does not remain in the tape feeder 21 (NO in Step 4), the controller 5 performs a component depletion process (Step 12). Examples of the component depletion process include a process of notifying an operator of the component depletion on the display unit 7, a process of stopping the operation of the mounting apparatus 100, and the like.

In addition, in the case where the tape feeder 21 exists which accommodates the electronic components 2 which are the same kind as the electronic components 2 which have been depleted, the controller 5 may perform, as the component depletion process, a process of supplying the electronic component 2 from the tape feeder 21 that accommodates the electronic components 2 of the same kind. Alternatively, in the case where there is no tape feeder 21 that accommodates the electronic components 2 which are the same kind as the electronic components 2 which have been depleted, the controller 5 may perform a process of causing another mounting apparatus 100 to mount the electronic component 2 thereon.

In Step 4, in the case where it is determined that the electronic component 2 exists in the image of the tape feeder 21 (YES in Step 4), the controller 5 then performs the process of Step 5.

Here, a description will be given on the case where it is determined that the component depletion occurs in the component depletion determination process based on the successive non-sucking errors (YES in Step 2) and determined that the component depletion is not caused in the component depletion determination process based on the image of the tape feeder 21 (YES in Step 4). In other words, such a case means the case where the non-sucking errors of the electronic components 2 by the sucking nozzles 31 successively occur in the same tape feeder 21, and the electronic component 2 remains in the tape feeder 21 in actuality.

In this case, for example, it is estimated that there occur abnormalities of the mounting apparatus 100, which include a nozzle failure such as a nozzle clogging, an operation failure of the movement of the sucking nozzle 31 in the vertical direction, an operation failure of the tape feeder 21, and a sucking position displacement of the electronic component 2 due to a position displacement of the tape feeder 21. In the mounting apparatus 100, this relationship is used. That is, in the case where it is determined that the component depletion occurs in the component depletion determination process based on the successive non-sucking errors and determined that the component depletion is not caused in the component depletion determination process based on the image of the tape feeder 21, the controller 5 can recognize that an abnormality occurs in any part of the mounting apparatus 100.

In Step 5, the controller 5 performs an abnormality determination process (process of determining whether an abnormality occurs or not in the mounting apparatus 100). The controller 5 performs the following five processes as the abnormality determination process, for example.

(1) The controller 5 takes an image of the tip end portion of the sucking nozzle 31 disposed at the image pickup position by at least one image pickup unit (abnormality detection sensor) of the second image pickup unit 52 and the third image pickup unit 53. In this case, typically, the controller 5 positions the sucking nozzle 31 that has caused the non-sucking error, out of the plurality of sucking nozzles 31, at the image pickup position, and an image of a tip end portion of the sucking nozzle 31 is taken by the image pickup unit. Then, on the basis of the image of the tip end portion of the sucking nozzle 31 taken, the controller 5 determines whether the tip end portion of the nozzle is chipped or not.

(2) The controller 5 causes the sucking nozzle 31 disposed at the image pickup position to move in the vertical direction to cause the second image pickup unit 52 (abnormality detection sensor) to take an image of a state in which the sucking nozzle 31 is moved in the vertical direction. In this case, typically, the controller 5 positions the sucking nozzle 31 that has caused the non-sucking error, out of the plurality of sucking nozzles 31, at the image pickup position, and an image of a state in which the sucking nozzle 31 is moved in the vertical direction is taken by the second image pickup unit 52. Then, on the basis of the image taken by the second image pickup unit 52, the controller 5 determines whether the sucking nozzle 31 normally moves in the vertical direction or not.

(3) The controller 5 sets a pressure of the sucking nozzle 31 which has caused the non-sucking error to a positive pressure by the air compressor 55 and measures a blow pressure at this time by the pressure sensor 56 (abnormality detection sensor). The controller 5 determines whether the blow pressure measured by the pressure sensor 56 is a normal value or not, thereby determining whether a nozzle clogging occurs in the sucking nozzle 31 or not.

(4) On the basis of the image of the tape feeder 21 taken by the first image pickup unit 51 (already obtained in Step 3), the controller 5 determines whether the tape feeder 21 is displaced from a normal position or not, thereby determining whether the sucking position of the electronic component 2 is displaced or not.

(5) The controller 5 feeds the electronic components 2 in step feeding by the feed mechanism 23 of the tape feeder 21. Then, the controller 5 takes images of the tape feeders 21 preceding to and subsequent to the feeder that feeds the electronic component 2 by the first image pickup unit 51. The controller 5 compares the images of the tape feeders 21 preceding to and subsequent to the feeder that feeds the electronic component 2 with each other, thereby determining whether the electronic components 2 are properly fed from the tape feeders 21 or not.

Herein, the case where all the abnormality determination processes of (1) to (5) are carried out will be described as an example, but at least one of the processes (1) to (5) may be carried out. Alternatively, from the processes (1) to (5), the process in which an abnormality is likely to occur in terms of the structure of the mounting apparatus 100 may be preferentially selected, for example.

When the abnormality determination process is carried out, the controller 5 determines whether or not a cause of the abnormality which is identified through the abnormality determination process can be repaired by the mounting apparatus 100 (Step 6). Whether the cause of the abnormality in the mounting apparatus 100 can be repaired by the mounting apparatus 100 or not is stored in the storage unit 6 in advance.

For example, in the case where the cause of the abnormality in the mounting apparatus 100 is a chipping of the tip end portion of the nozzle (corresponding to the process (1)), a nozzle clogging (corresponding to the process (3)), or a sucking position displacement of the electronic component 2 (corresponding to the process (4)), the controller 5 determines that the abnormality can be repaired (YES in Step 6). On the other hand, in the case where the cause of the abnormality in the mounting apparatus 100 is an operation failure in the vertical direction of the sucking nozzle 31 (corresponding to the process (2)) or an operation failure of the tape feeder 21 (corresponding to the process (5)), the controller 5 determines that it may be impossible to repair the abnormality (NO in Step 6).

In the case where it may be impossible to repair the abnormality by the mounting apparatus 100 (NO in Step 6), the controller 5 causes the display unit 7 to display the cause of the abnormality (for example, the operation failure in the vertical direction of the sucking nozzle 31 (corresponding to the process (2)) or the operation failure of the tape feeder 21 (corresponding to the process (5))) (Step 11). As a result, an operator is notified of the cause of the abnormality. At this time, the controller 5 stops the operation of the mounting apparatus 100. As a method of notifying the operator of the cause of the abnormality, a method of notifying the operator of the cause of the abnormality with sounds may be used instead of the method of displaying the cause of the abnormality on the display unit 7.

In this embodiment, as described above, the mounting apparatus 100 notifies the operator of the cause of the abnormality in the mounting apparatus 100, so the operator can easily know the cause of the abnormality. This makes a response of the repair easy. It should be noted that it is not always necessary to notify the operator of the cause of the abnormality. For example, a method of simply using a buzzer to notify the operator of an occurrence of the abnormality may be used.

In the case where it is determined that the cause of the abnormality can be repaired by the mounting apparatus 100 in Step 6 (for example, the chipping of the tip end portion of the nozzle (corresponding to the process (1)), the nozzle clogging (corresponding to the process (3)), or the sucking position displacement of the electronic component 2 (corresponding to the process (4))) (YES in Step 6), the controller 5 then performs Step 7. In Step 7, the controller 5 performs a process of repairing the abnormality in the mounting apparatus 100.

For example, in the case where the cause of the abnormality is the chipping of the tip end portion of the nozzle (corresponding to the process (1)), the controller 5 causes the mounting head 30 to move to a position above the nozzle changer 61 (repair unit). Then, the controller 5 causes the sucking nozzle 31, the nozzle tip end portion of which is chipped, to be set to the operation position and to move downward to be inserted into the nozzle holding hole 62 of the nozzle changer 61. Then, the controller 5 rotates the sucking nozzle 31 to detach the sucking nozzle 31 from the turret 32. Then, the controller 5 attaches a new sucking nozzle 31 which is prepared in the nozzle holding hole 62 to the turret 32 at the position thereof. As a result, the chipping of the nozzle tip end portion is automatically repaired.

Further, for example, in the case where the cause of the abnormality is the nozzle clogging (corresponding to the process (3)), the controller 5 increases the blow pressure of the sucking nozzle 31 in which the nozzle clogging has occurred by the air compressor 55 (repair unit). As a result, foreign matters that clog in the sucking nozzle 31 are removed, and the nozzle clogging is automatically repaired.

Further, in the case where the cause of the abnormality is the sucking position displacement of the electronic component 2 (corresponding to the process (4)), the controller 5 (repair unit) determines a position displacement amount of the electronic component 2 with respect to the sucking position of the sucking nozzle 31 on the basis of the image taken by the first image pickup unit 51. Then, on the basis of the determined position displacement amount of the electronic component 2, the controller 5 corrects the sucking position of the sucking nozzle 31. As a result, the sucking position displacement of the electronic component 2 is automatically corrected.

As described above, in this embodiment, in the case where the abnormality occurs in the mounting apparatus 100, the cause of the abnormality is automatically identified, and the abnormality is automatically repaired by the mounting apparatus 100. Thus, in the case where the abnormality occurs in the mounting apparatus 100, it is possible to eliminate such a burdensome operation that the operator identifies the cause of the abnormality and repairs the abnormality.

Upon performing the abnormality repair processes, the controller 5 confirms a sucked state of the electronic component 2 with respect to the sucking nozzle 31 (Step 8).

For example, in the case where the cause of the abnormality is the chipping of the tip end portion of the nozzle (corresponding to the process (1)), the controller 5 positions the sucking nozzle 31 newly attached to the turret 32 to the operation position and causes the sucking nozzle 31 to suck the electronic component 2. Then, the controller 5 positions the sucking nozzle 31 that sucks the electronic component 2 to the image pickup position to take an image thereof by at least one of the second image pickup unit 52 and the third image pickup unit 53. The controller 5 confirms the sucked state of the electronic component 2 with respect to the sucking nozzle 31 on the basis of the image of the sucking nozzle 31 taken by the image pickup unit.

For example, in the case where the cause of the abnormality is the nozzle clogging (corresponding to the process (3)), the controller 5 positions the sucking nozzle 31 in which the nozzle clogging occurs to the operation position to suck the electronic component 2 by the sucking nozzle 31. Then, the controller 5 positions the sucking nozzle 31 that sucks the electronic component 2 to the image pickup position to take an image thereof by at least one of the second image pickup unit 52 and the third image pickup unit 53. The controller 5 confirms the sucked state of the electronic component 2 with respect to the sucking nozzle 31 on the basis of the image of the sucking nozzle 31 taken.

For example, in the case where the cause of the abnormality is the sucking position displacement of the electronic component 2 (corresponding to the process (4)), the controller 5 corrects the sucking position of the sucking nozzle 31 and sucks the electronic component 2 by the sucking nozzle 31. Then, the controller 5 positions the sucking nozzle 31 that sucks the electronic component 2 to the image pickup position to take an image thereof by at least one of the second image pickup unit 52 and the third image pickup unit 53. The controller 5 confirms the sucked state of the electronic component 2 with respect to the sucking nozzle 31 on the basis of the image of the sucking nozzle 31 taken.

Upon confirmation of the sucked state of the electronic component 2 with respect to the sucking nozzle 31, the controller 5 then determines whether or not the electronic component 2 is normally sucked by the sucking nozzle 31 (Step 9).

In the case where the electronic component 2 is normally sucked with respect to the sucking nozzle 31 (YES in Step 9), the controller 5 performs again the process of Step 1. On the other hand, in the case where the electronic component 2 is not normally sucked with respect to the sucking nozzle 31 (NO in Step 9), the controller 5 gives notification of the cause of the abnormality. That is, in the case where the electronic component 2 is not normally sucked with respect to the sucking nozzle 31 even though the abnormality repair process is performed by the mounting apparatus 100, the controller 5 gives the notification of the cause of the abnormality.

In this case, the controller 5 causes the display unit 7 to display the cause of the abnormality (for example, the chipping of the nozzle tip end portion (corresponding to the process (1)), the nozzle clogging (corresponding to the process (3)), or the sucking position displacement of the electronic component 2 (corresponding to the process (4))) (Step 11). As a result, the operator is notified of the cause of the abnormality. At this time, the controller 5 stops the operation of the mounting apparatus 100. As the method of giving the notification of the cause of the abnormality, a method of notifying the operator of the cause of the abnormality with sounds may be used instead of the method of displaying the cause of the abnormality on the display unit 7.

In this embodiment, as described above, the mounting apparatus 100 notifies the operator of the cause of the abnormality in the mounting apparatus 100, so the operator can easily know the cause of the abnormality. This makes a response of the repair easy. It should be noted that it is not always necessary to notify the operator of the cause of the abnormality. For example, a method of simply using a buzzer to notify the operator of an occurrence of the abnormality may be used.

In the explanation of FIG. 5, it is determined whether or not the cause of the abnormality identified by the abnormality determination process can be repaired by the mounting apparatus 100 (Step 6), and if the repair can be achieved, the abnormality is automatically repaired (Step 7). However, the automatic repair process may not necessarily be performed. In this case, whether or not the cause of the abnormality can be repaired by the mounting apparatus 100 is not determined (see Step 6), and the cause of the abnormality (corresponding to any one of the processes (1) to (5)) identified in the abnormality determination process (see Step 5) is displayed on the display unit 7 (see Step 11). Alternatively, the notification of the cause of the abnormality is given by an audio unit.

In Steps 3 and 4, when whether the electronic component 2 remains or not is determined by taking the image of the tape feeder 21, the controller 5 may feed the electronic components 2 multiple times with the feed mechanism 23, and the image of the tape feeder 21 is taken each time the electronic component 2 is fed. As a result, it is possible to improve the accuracy of the component depletion determination process (second component depletion determination process).

In the case where it is determined that the electronic component 2 remains in Step 4, the sucking operation of the electronic component 2 by the sucking nozzle 31 may be performed again. Then, in the case where the electronic component 2 is not sucked by the sucking nozzle 31 even though the electronic component 2 is tried to be sucked by the sucking nozzle 31, the abnormality determination process may be performed.

In the explanation of FIG. 5, in the case where the successive non-sucking error count exceeds the prescribed count even in one of the plurality of tape feeders 21, the processes of Step 3 and subsequent thereto are performed. On the other hand, in the case where the number of tape feeders 21 in which the successive non-sucking error count exceeds the prescribed count becomes larger than a predetermined number, the processes of Step 3 and subsequent thereto may be performed collectively for the tape feeders 21 in which the successive non-sucking error count exceeds the prescribed count.

It should be noted that the present disclosure can also take the following configurations.

(1) A mounting apparatus, including:

a supply unit configured to supply an electronic component;

a holding unit configured to hold the electronic component supplied from the supply unit and mount the electronic component on a substrate;

a first sensor and a second sensor configured to detect a component depletion of the electronic component supplied from the supply unit; and

a controller configured to perform a first component depletion determination process in which whether the component depletion of the electronic component is caused is determined on the basis of an output from the first sensor, and when it is determined that the component depletion is caused in the first component depletion determination process, perform a second component depletion determination process in which whether the component depletion is caused is determined on the basis of an output from the second sensor.

(2) The mounting apparatus according to Item (1), in which

the second sensor is an image sensor configured to take an image of the supply unit, and

the controller determines, in the second component depletion determination process, whether the component depletion is caused on the basis of image information of the supply unit, which is an output from the image sensor.

(3) The mounting apparatus according to Item (1) or (2), in which

the first sensor is a holding detection sensor configured to detect whether the electronic component is held by the holding unit, and

the controller determines, in the first component depletion determination process, whether the electronic components are not held by the holding unit successively on the basis of an output from the holding detection sensor, and when the electronic components are not held successively, determines that the component depletion is caused.

(4) The mounting apparatus according to any one of Items (1) to (3), further including

a notification unit configured to notify an operator of an abnormality in the mounting apparatus, in which

when it is determined that the component depletion is caused in the first component depletion determination process, and it is determined that the component depletion is not caused in the second component depletion determination process, the controller determines that the abnormality is generated in the mounting apparatus and notifies the abnormality by the notification unit.

(5) The mounting apparatus according to Item (4), further including

an abnormality detection sensor configured to identify a cause of the abnormality in the mounting apparatus, in which

the controller identifies the cause of the abnormality in the mounting apparatus on the basis of an output from the abnormality detection sensor and notifies the cause of the abnormality in the mounting apparatus by the notification unit.

(6) The mounting apparatus according to any one of Items (1) to (3), further including

a repair unit configured to repair an abnormality in the mounting apparatus, in which

when it is determined that the component depletion is caused in the first component depletion determination process, and it is determined that the component depletion is not caused in the second component depletion determination process, the controller determines that the abnormality is generated in the mounting apparatus and repairs the abnormality by the repair unit.

(7) The mounting apparatus according to Item (6), further including

an abnormality detection sensor configured to identify a cause of the abnormality in the mounting apparatus, in which

the controller identifies the cause of the abnormality in the mounting apparatus on the basis of an output from the abnormality detection sensor and repairs the abnormality identified in the mounting apparatus by the repair unit.

(8) The mounting apparatus according to any one of Items (1) to (3), further including

an abnormality detection sensor configured to identify a cause of an abnormality in the mounting apparatus, in which

when it is determined that the component depletion is caused in the first component depletion determination process, and it is determined that the component depletion is not caused in the second component depletion determination process, the controller determines that the abnormality is generated in the mounting apparatus and identifies the cause of the abnormality in the mounting apparatus on the basis of an output from the abnormality detection sensor.

(9) The mounting apparatus according to Item (8), further including:

a notification unit configured to notify an operator of the abnormality in the mounting apparatus; and

a repair unit configured to repair the abnormality in the mounting apparatus, in which

the controller determines whether the cause of the abnormality identified on the basis of the output from the abnormality detection sensor is capable of being repaired by the repair unit, repairs the abnormality in the mounting apparatus by the repair unit when the abnormality is capable of being repaired, and notifies the cause of the abnormality by the notification unit when the abnormality is not capable of being repaired.

(10) A component depletion determination method, including:

performing a first component depletion determination process in which whether a component depletion of an electronic component is caused is determined on the basis of an output from a first sensor that detects the component depletion of the electronic component supplied from a supply unit that supplies the electronic component to a holding unit that holds the electronic component and mounts the electronic component on a substrate; and

performing, when it is determined that the component depletion is caused in the first component depletion determination process, a second component depletion determination process in which whether the component depletion is caused is determined on the basis of an output from a second sensor that detects the component depletion of the electronic component.

(11) A program causing a mounting apparatus to execute

a step of performing a first component depletion determination process in which whether a component depletion of an electronic component is caused is determined on the basis of an output from a first sensor that detects the component depletion of the electronic component supplied from a supply unit that supplies the electronic component to a holding unit that holds the electronic component and mounts the electronic component on a substrate, and

a step of performing, when it is determined that the component depletion is caused in the first component depletion determination process, a second component depletion determination process in which whether the component depletion is caused is determined on the basis of an output from a second sensor that detects the component depletion of the electronic component.

The present disclosure contains subject matter related to that disclosed in Japanese Priority Patent Application JP 2011-241144 filed in the Japan Patent Office on Nov. 2, 2011, the entire content of which is hereby incorporated by reference.

It should be understood by those skilled in the art that various modifications, combinations, sub-combinations and alterations may occur depending on design requirements and other factors insofar as they are within the scope of the appended claims or the equivalents thereof.

What is claimed is:

1. A mounting apparatus, comprising:
a supply unit configured to supply an electronic component;
a holding unit configured to hold the electronic component supplied from the supply unit and mount the electronic component on a substrate;
a first sensor and a second sensor configured to detect a component depletion of the electronic component supplied from the supply unit; and
a controller configured to perform a first component depletion determination process in which whether the component depletion of the electronic component is caused is determined on the basis of an output from the first sensor, and when it is determined that the component depletion is caused in the first component depletion determination process, perform a second component depletion determination process in which whether the component depletion is caused is determined on the basis of an output from the second sensor.

2. The mounting apparatus according to claim 1, wherein
the second sensor is an image sensor configured to take an image of the supply unit, and
the controller determines, in the second component depletion determination process, whether the component depletion is caused on the basis of image information of the supply unit, which is an output from the image sensor.

3. The mounting apparatus according to claim 1, wherein
the first sensor is a holding detection sensor configured to detect whether the electronic component is held by the holding unit, and
the controller determines, in the first component depletion determination process, whether the electronic components are not held by the holding unit successively on the basis of an output from the holding detection sensor, and when the electronic components are not held successively, determines that the component depletion is caused.

4. The mounting apparatus according to claim 1, further comprising
a notification unit configured to notify an operator of an abnormality in the mounting apparatus, wherein
when it is determined that the component depletion is caused in the first component depletion determination process, and it is determined that the component depletion is not caused in the second component depletion determination process, the controller determines that the abnormality is generated in the mounting apparatus and notifies the abnormality by the notification unit.

5. The mounting apparatus according to claim 4, further comprising
an abnormality detection sensor configured to identify a cause of the abnormality in the mounting apparatus, wherein
the controller identifies the cause of the abnormality in the mounting apparatus on the basis of an output from the abnormality detection sensor and notifies the cause of the abnormality in the mounting apparatus by the notification unit.

6. The mounting apparatus according to claim 1, further comprising
a repair unit configured to repair an abnormality in the mounting apparatus, wherein
when it is determined that the component depletion is caused in the first component depletion determination process, and it is determined that the component depletion is not caused in the second component depletion determination process, the controller determines that the abnormality is generated in the mounting apparatus and repairs the abnormality by the repair unit.

7. The mounting apparatus according to claim 6, further comprising
an abnormality detection sensor configured to identify a cause of the abnormality in the mounting apparatus, wherein
the controller identifies the cause of the abnormality in the mounting apparatus on the basis of an output from the abnormality detection sensor and repairs the abnormality identified in the mounting apparatus by the repair unit.

8. The mounting apparatus according to claim 1, further comprising
an abnormality detection sensor configured to identify a cause of an abnormality in the mounting apparatus, wherein
when it is determined that the component depletion is caused in the first component depletion determination process, and it is determined that the component depletion is not caused in the second component depletion determination process, the controller determines that the abnormality is generated in the mounting apparatus and identifies the cause of the abnormality in the mounting apparatus on the basis of an output from the abnormality detection sensor.

9. The mounting apparatus according to claim 8, further comprising:
a notification unit configured to notify an operator of the abnormality in the mounting apparatus; and
a repair unit configured to repair the abnormality in the mounting apparatus, wherein
the controller determines whether the cause of the abnormality identified on the basis of the output from the abnormality detection sensor is capable of being repaired by the repair unit, repairs the abnormality in the mounting apparatus by the repair unit when the abnormality is capable of being repaired, and notifies the cause of the abnormality by the notification unit when the abnormality is not capable of being repaired.

10. A component depletion determination method, comprising:
performing a first component depletion determination process in which whether a component depletion of an electronic component is caused is determined on the basis of an output from a first sensor that detects the component depletion of the electronic component supplied from a supply unit that supplies the electronic component to a holding unit that holds the electronic component and mounts the electronic component on a substrate; and
performing, when it is determined that the component depletion is caused in the first component depletion determination process, a second component depletion determination process in which whether the component depletion is caused is determined on the basis of an output from a second sensor that detects the component depletion of the electronic component.

11. A program causing a mounting apparatus to execute
a step of performing a first component depletion determination process in which whether a component depletion of an electronic component is caused is determined on the basis of an output from a first sensor that detects the component depletion of the electronic component supplied from a supply unit that supplies the electronic component to a holding unit that holds the electronic component and mounts the electronic component on a substrate, and
a step of performing, when it is determined that the component depletion is caused in the first component depletion determination process, a second component depletion determination process in which whether the component depletion is caused is determined on the basis of an output from a second sensor that detects the component depletion of the electronic component.
